(19) United States
(12) Patent Application Publication
(10) Pub. No.: US 2018/0138558 A1
(43) Pub. Date: May 17, 2018

(54) BATTERY WITH DISPLAY FUNCTION AND ELECTRONIC DEVICE CONTAINING THE SAME

(71) Applicant: FEITIAN TECHNOLOGIES CO., LTD., BEIJING (CN)

(72) Inventors: ZHOU LU, BEIJING (CN); HUAZHANG YU, BEIJING (CN)

(21) Appl. No.: 15/868,985

(22) Filed: Jan. 11, 2018

Related U.S. Application Data
(63) Continuation of application No. PCT/CN2016/105120, filed on Nov. 8, 2016.

(30) Foreign Application Priority Data
Jan. 29, 2016 (CN) 201610065895.6

(51) Int. Cl. H01M 10/48; G02F 1/1343; G02F 1/1339; G02F 1/1337; G02F 1/1362; G02F 1/1345; G02F 1/1368; G02F 1/167; H01M 10/42

(52) U.S. Cl. CPC H01M 10/488; G02F 1/13439; G02F 1/1339; G02F 1/1337; G02F 1/136286; G02F 1/13454; H05K 1/181; G02F 1/167; G02F 1/134309; H01M 10/425; G02F 2201/123; G02F 2201/121; H05K 2201/10037; G02F 1/1368

(57) ABSTRACT

The present invention provides a battery with display function and an electronic device containing the same; the battery includes a non-volatile display layer, a substrate layer and a power layer, the non-volatile display layer includes a first electrode layer, a display medium layer, a second electrode layer and a transparent medium layer; the power layer includes a first electrode current collector, a first electrode material, electrolyte, a second electrode material and a second electrode current collector; the substrate layer is a PCB substrate, both the second electrode current collector and the first electrode layer are placed on the PCB substrate; the second electrode current collector, the PCB substrate and the first electrode layer constitute a PCB structure.

### CROSS-REFERENCE TO RELATED APPLICATIONS

This application is a continuation of International Application No. PCT/CN2016/105120, filed on Nov. 8, 2016, which claims priority of Chinese Patent Application No. 201610065895.6, filed on Jan. 29, 2016, which is hereby incorporated by reference in its entirety.

### TECHNICAL FIELD

The present invention relates to the field of electronic technology and, in particular, to a battery with display function and an electronic device containing the same.

### BACKGROUND

With development of electronic technology, there are more and more kinds of electronic devices, which are widely used in daily life. The electronic device in the prior art generally has a displayer and a battery. The displayer and the battery have to be arranged separately on the electronic device because the displayer and the battery can not be integrated into one electronic element. Considering the portability, a volume of an electronic device becomes smaller and smaller. In order to reduce the volume of the electronic device, the volume of the battery and/or the displayer needs to be reduced correspondingly. Reduction of the volume of the battery in the electronic device will lead to a limitation of battery capacity. Therefore, the battery has to be charged or changed frequently and bad experience will be brought to a user of the electronic device. While reduction of the volume of the display in the electronic device will cause reduction of the display information, which brings bad experience to the user as well.

### SUMMARY

The present invention provides a battery with display function and an electronic device containing the same, in order to solve a problem in prior art that a limitation of battery capacity caused by limited volume.

The present invention provides a battery with display function, including a non-volatile display layer, a substrate layer and a power layer, where the substrate layer is located between the non-volatile display layer and the power layer;
where, the non-volatile display layer includes a first electrode layer, a display medium layer, a second electrode layer and a transparent medium layer, the first electrode layer is located between the display medium layer and the substrate layer, the display medium layer is located between the first electrode layer and the second electrode layer; the second electrode layer is located between the transparent medium layer and the display medium layer, the second electrode layer is placed on a surface of the transparent media layer, the transparent medium layer contacts the display medium layer via the surface, the display medium layer is filled with display cells, the transparent medium layer and the second electrode layer are made of transparent material;
the power layer includes a first electrode current collector, a first electrode material, electrolyte, a second electrode material and a second electrode current collector, the electrolyte is located between the first electrode material and the second electrode material, the first electrode material is located between the first electrode current collector and the electrolyte, and the second electrode material is located between the second electrode current collector and the electrolyte; and
the substrate layer is a PCB substrate, both the second electrode current collector and the first electrode layer are placed on the PCB substrate; and the second electrode current collector, the PCB substrate and the first electrode layer constitute a PCB structure.

Optionally, the transparent medium layer and the PCB substrate forms a sealed space with the display medium layer sealed in the sealed space.

Optionally, the display cells are microcapsules or liquid crystal molecules.

Optionally, the microcapsule contains transparent liquid, and a plurality of white particles with charges of a first polarity and a plurality of black particles with charges of a second polarity in the transparent liquid.

Optionally, when the display cells are liquid crystal molecules, the battery further includes a first alignment film and a second alignment film, the first alignment film is located between the first electrode layer and the display medium layer; the second alignment film is located between the display medium layer and the second electrode layer.

Optionally, the liquid crystal molecules are bistable liquid crystal molecules.

Optionally, the first electrode layer includes a first electrode and a first electrode lead connected to the first electrode, the second electrode layer includes a second electrode and a second electrode lead connected to the second electrode; the first electrode and the second electrode are located above the display medium layer and under the display medium layer, respectively.

Optionally, the battery further includes a first connection part;
the first electrode is connected to the first connection part via the first electrode lead and obtains external power supply via the first connection part; and the second electrode is connected to the first connection part via the second electrode lead and obtains external power supply via the first connection part.

Optionally, the first electrode is a pixel electrode, and the second electrode is a shared electrode;
the first electrode layer includes a plurality of scan lines, a plurality of data lines and a plurality of pixel cells; each pixel cell is located in a matrix formed by the scan lines and the data lines in the first electrode layer, and is surrounded by a corresponding scan line and a corresponding data line.

Optionally, the first electrode layer further includes a display driver, the display driver is connected to the pixel cells in the first electrode layer via the scan lines and the data lines and is configured to drive the pixel cells in the first electrode layer.

Optionally, when the first electrode is a shared electrode, the second electrode is a pixel electrode;
the second electrode layer includes a plurality of scan lines, a plurality of data lines and a plurality of pixel cells; each pixel cell is located in a matrix formed by the scan lines and the data lines in the second electrode layer and is surrounded by a corresponding scan line and a corresponding data line.

Optionally, the second electrode further includes a display driver, the display driver is connected to the pixel cells in the second electrode layer via the scan lines and the data lines and is configured to drive the pixel cells in the second electrode layer.

Optionally, the pixel cell includes a thin-film transistor and a pixel electrode connected to the thin-film transistor.

Optionally, the battery further includes a first electrode wiring and a second electrode wiring; the second electrode current collector, the first electrode wiring and the second wiring are located on a same plane; the second electrode wiring and the second electrode current collector are conductive; the first electrode wiring and the first electrode current collector are conductive, and the first electrode wiring is insulated to the second electrode current collector and the second electrode wiring.

The present invention further provides an electronic device containing the battery and the electronic device further includes a main circuit board, the main circuit board is arranged with one or more electronic elements, the battery is connected to the main circuit board via a first junction part located at an edge of the battery itself.

Optionally, the battery is connected to the main circuit board via a second junction located at the edge of the battery itself.

Optionally, the electronic device further includes an auxiliary circuit board; the auxiliary circuit board is connected to the mail circuit board via a third junction located at an edge of the auxiliary circuit board itself; the auxiliary circuit board is arranged with one or more electronic elements.

According to the present invention, one of the electrode current collectors in the battery is multiplexed as one surface layer of a printed circuit board and implements display function on another surface layer of the printed circuit board, so as to implement integration of a displayer and a battery. In this way, an electronic device on which the battery is located requires no extra displayer, which reduces limitation of volume of the battery and the displayer in the electronic device without enlarging volume of the electronic device, and promoting the battery capacity of the electronic device and the using experience of the user as well.

### BRIEF DESCRIPTION OF THE DRAWINGS

FIG. 1 is a cross-sectional diagram of a battery with display function according to an embodiment of the present invention;

FIG. 2 is a cross-sectional diagram of a display medium layer according to an embodiment of the present invention;

FIG. 3 is diagram of an display medium layer, an electrode layer and an alignment film according to an embodiment of the present invention;

FIG. 4 is top view of a battery with display function according to an embodiment of the present invention;

FIG. 5 is a diagram of a first electrode layer according to an embodiment of the present invention;

FIG. 6 is a diagram of liquid crystal molecules in twisted planar state according to an embodiment of the present invention;

FIG. 7 is diagram of liquid crystal molecules in conic state according to an embodiment of the present invention;

FIG. 8 is an display effect diagram of a battery with display function according to an embodiment of the present invention;

FIG. 9 is another display effect diagram of a battery with display function according to an embodiment of the present invention;

FIG. 10 is a diagram of a second electrode current collector according to an embodiment of the present invention;

FIG. 11 is a diagram of a first electrode current collector according to an embodiment of the present invention;

FIG. 12 is a diagram of a central part and an edge part of the second electrode collector according to an embodiment of the present invention;

FIG. 13 is a diagram of an electronic device according to an embodiment of the present invention;

FIG. 14 is a diagram of another electronic device according to an embodiment of the present invention; and

FIG. 15 is a diagram of still another electronic device according to an embodiment of the present invention.

### DETAILED DESCRIPTION

Embodiments of the present invention are described clearly and completely in conjunction with the accompanying drawings of the embodiments of the present invention as follows. Apparently, the described embodiments are merely a part of but not all of the embodiments according to the present invention. Based on the described embodiments of the present invention, other embodiments obtained by those skilled in the art without any creative work belong to the scope of protection of the present invention.

The embodiments of the present invention provide a battery with display function, which includes a non-volatile display layer, a substrate layer and a power layer, and the substrate layer is located between the non-volatile display layer and the power layer.

The non-volatile includes a first electrode layer, a display medium layer, a second electrode layer and a transparent medium layer; the first electrode layer is located between the display medium layer and the substrate layer, the display medium layer is located between the first electrode layer and the second electrode layer, the second electrode layer is located between the transparent medium layer and the display medium layer; the second electrode layer is placed on a surface of the transparent medium layer; the transparent medium layer contacts the display medium layer via the surface; the display medium layer is filled with display cells; and, the transparent medium layer and the second electrode layer are made up of transparent material.

The power layer includes a first electrode current collector, a first electrode material, electrolyte, a second electrode material and a second electrode current collector; the electrolyte is located between the first electrode material and the second electrode material; the first electrode material is located between the first electrode current collector and the electrolyte, the second electrode material is located between the second electrode current collector and the electrolyte.

The substrate layer is a PCB substrate, both the second electrode current collector and the first electrode layer are placed on the PCB substrate; the second electrode current collector, the PCB substrate and the first electrode layer constitute a PCB structure.

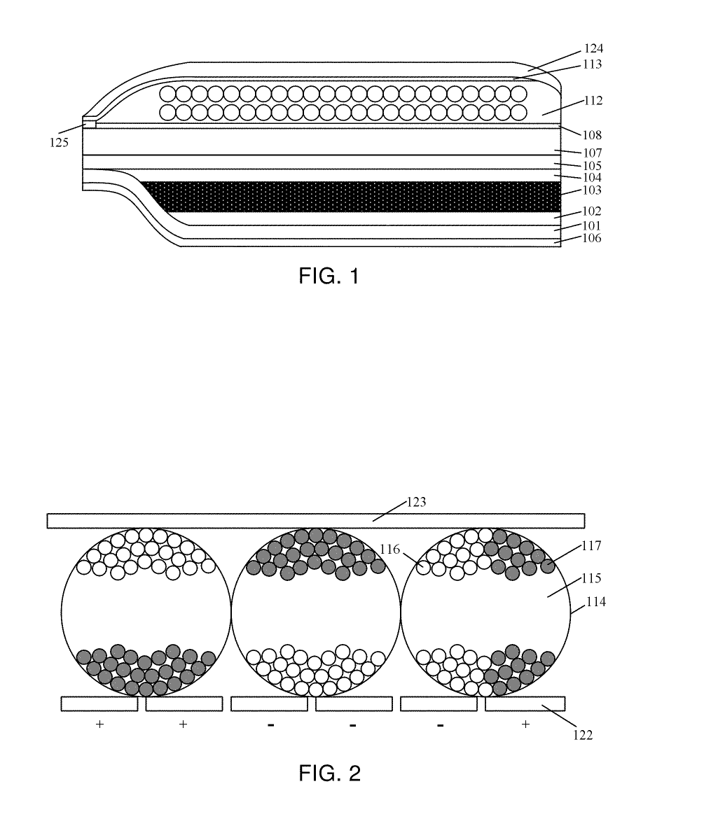

FIG. 1 shows a cross-sectional diagram of an battery with display function in according to an embodiment of the present invention. The battery includes a first electrode current collector 101, a first electrode material 102, the electrolyte 103, the second electrode material 104, the second electrode current collector 105, an insulated layer 106, PCB (Printed Circuit Board, printed circuit board) substrate 107, a first electrode layer 108, a display medium layer 112, a second electrode layer 113 and a transparent medium layer 124, the electrolyte 103 is located between the first electrode material 102 and a second electrode material 104, the first electrode material 102 is located between the first electrode current collector 101 and the electrolyte 103, the second electrode material 104 is located between the second electrode current collector 105 and the electrolyte 103, the first electrode current collector 101 is located between the insulated layer 106 and the first electrode material 102; the second electrode current collector 105 is located between the second electrode material 104 and the PCB substrate 107, the PCB substrate 107 is located between the second electrode current collector 105 and the first electrode layer 108; the first electrode layer 108 is located between the PCB substrate 107 and the display medium layer 112; the display medium layer 112 is located between the first electrode layer 108 and the second electrode layer 113; and the second electrode layer 113 is located between the display medium layer 112 and the transparent medium layer 124.

Where, the second electrode layer 113 is placed on the surface of the transparent medium layer 124; the transparent medium layer 124 contacts the display medium layer 112 via the surface; the transparent medium layer 124 and the second electrode layer 113 are both transparent medium, which can transparently transmit the light illuminating on the transparent medium layer 124; the second electrode current collector 105 and the first electrode layer 108 are placed on the PCB substrate 107, the transparent medium layer 124 and the PCB substrate 107 forms a sealed space with the display medium layer 112 sealed in the sealed space; the second electrode current collector 105, the PCB substrate 107 and the first electrode layer 108 constitute a PCB structure; and the PCB structure is flexible PCB, and may be a dual face PCB or a PCB with multiple layers.

Further, the first electrode layer 108 includes a first electrode and a first electrode lead connected to the first electrode; the second electrode layer 113 includes a second electrode and a second electrode lead connected to the second electrode; where, the first electrode and the second electrode are located under the display medium layer 112 and above the display medium layer 112 respectively, to impose a voltage to the display cells in the display medium layer 112.

The insulated layer 106 seals the edge of the battery; the transparent medium layer 124 and the PCB substrate 107 forms a sealed space with the display medium layer 112 sealed in the sealed space; the display medium layer 112 is filled with display cells, and the display cells may be microcapsules or liquid crystal molecules.

Specifically, when the display cells in the display medium layer 112 are microcapsules 114, the microcapsules 114 contains transparent liquid 115, and a plurality of white particle 116 with charges of a first polarity and a plurality of black particles 117 with charges of a second polarity in the transparent liquid; the first electrode in the first electrode layer 108 is a shared electrode 123; the second electrode in the second electrode layer 113 is a pixel electrode 122; the white parcel 116 and the black parcel 117 are driven by an electric field between the pixel electrode 122 and the shared electrode 123, as shown in FIG. 2. Where, if the charges of the first polarity are positive charge, the charges of the second polarity are negative charge; if the charges of the first polarity are negative charge, the charges of the second polarity are positive charge.

When the display cells are liquid crystal molecules 131, the battery in the present embodiment further includes a first alignment film 132 and a second alignment film 133; the first alignment film 132 is located between the first electrode layer 108 and the display medium layer 112, the second alignment film 133 is located between the display medium layer 112 and the second electrode layer 113, as shown in FIG. 3. Where, the liquid crystal molecules in the display medium layer 112 may be bistable liquid crystal molecules.

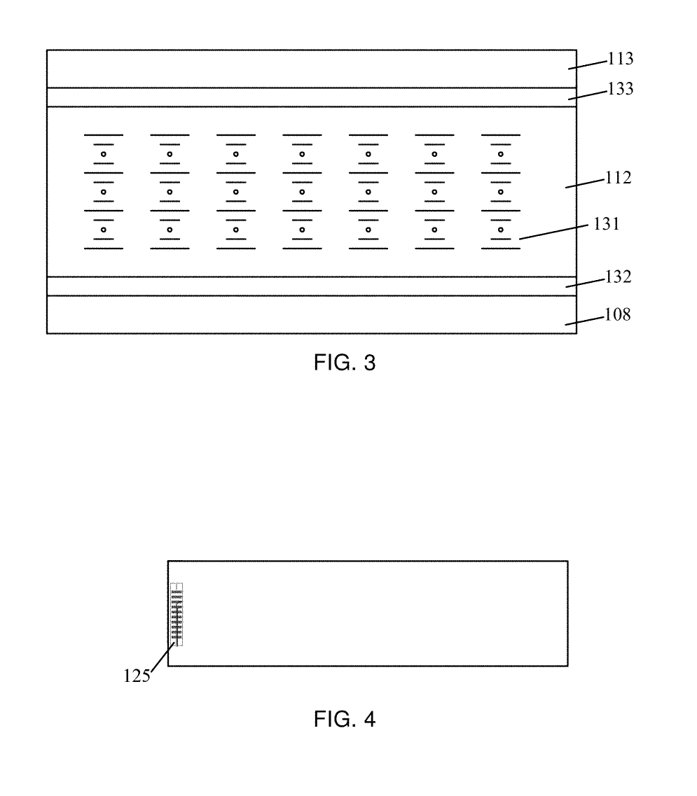

Further, the battery in the embodiment of the present invention further includes a first connection part 125, as shown in FIG. 4. The first connection part 125 is located at the edge of the battery and may be arranged on the PCB substrate 107; the first electrode is connected to the first connection part 125 via the first electrode lead of the first electrode layer 108 and obtains external power supply via the first connection part 125; the second electrode is connected to the first connection part 125 via the second electrode lead on the second electrode layer 113 and obtains external power supply via the first connection part 125.

Where, the first connection part 125 can be an edge connector (also called golden finger), the first electrode lead on the first electrode layer 108 and the second electrode lead on the second electrode layer 113 are connected to conductive medium contained in the first connection part 125, the conductive medium may be a copper pad or other conductive medium. When the first electrode is shared electrode, the second electrode is a pixel electrode; when the first electrode is a pixel electrode, the second electrode is shared electrode.

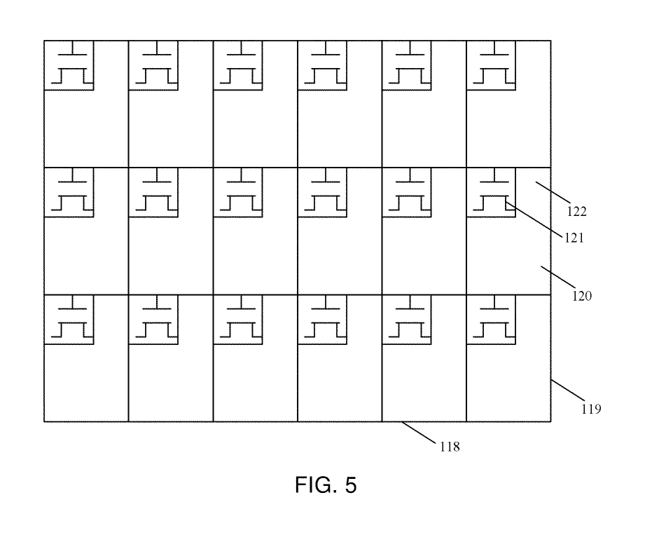

In one implementation of the present invention, the first electrode in the first electrode layer 108 is a pixel electrode. Specifically, the first electrode layer 108 includes a plurality of scan lines 118, a plurality of data lines 119 and a plurality of the pixel cells 120. As shown in FIG. 5, each pixel cell 120 is located in a matrix formed by the scan lines 118 and the data lines 119 in the first electrode layer 108 and is surrounded by a corresponding scan line 118 and a corresponding data line 119. Where, the pixel cell 120 includes a thin-film transistor 121 and a pixel electrode 122 connected to the thin-film transistor 121.

Further, the first electrode layer 108 further includes a display driver, which is connected to the pixel cell 120 in the first electrode layer 108 via the scan line 118 and the data line 119, and is configured to drive the pixel cell 120 in the first electrode layer 108.

Correspondingly, the second electrode layer 113 includes a shared electrode 123, and the shared electrode 123 may be ITO (Indium Tin Oxides, indium tin oxides) or any other transparent conductive thin film.

In another implementation in the present invention, the second electrode in the second electrode layer 113 is a pixel electrode. Specifically, the second electrode layer 113 includes a plurality of scan lines, a plurality of data lines and a plurality of pixel electrodes; and each pixel cell is located in a matrix formed by the scan lines and the data lines in the second electrode layer 113, and is surrounded by a corresponding scan line and a corresponding data line. Where, the pixel cell includes a thin-film transistor and a pixel electrode connected to the thin-film transistor.

Further, the second electrode layer 113 further includes a display driver, the display driver is connected to the pixel cells in the second electrode layer 113 via the scan lines and the data lines, and is configured to drive the pixel cells in the second electrode layer 113.

Correspondingly, the first electrode layer 108 includes a shared electrode, which may be ITO, or any other transparent conductive thin film.

Based on the structure above, when the display cells in the display medium layer 112 are microcapsules 114, each microcapsule 114 in the display medium layer 112 is driven by an electric field between the pixel electrode 122 and the shared electrode 123. As shown in FIG. 2, if the white particles 116 in the microcapsule 114 is positively charged and the black particles 117 in the microcapsule 114 is negatively charged, when the electric field between the pixel electrode 122 and the shared electrode 123 is positive, the white particles 116 positively charged move to the top of the microcapsule 114, and the black particles 117 negatively charged move to the bottom of the microcapsule 114, so that the microcapsule 114 appears white; when the electric field between the pixel electrode 122 and the shared electrode 123 is negative, the white particles 116 positively charged move to the bottom of the microcapsule 114, the black particles 117 negatively charged move to the top of the microcapsule 114, so that the microcapsule 114 appears black.

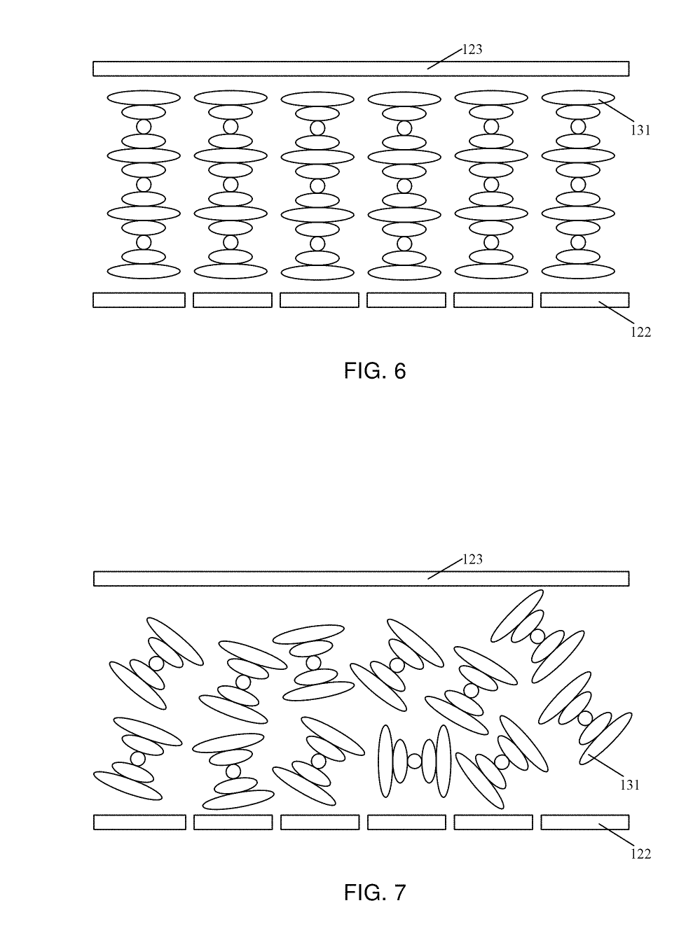

When the display cells are the liquid crystal molecules 131, each liquid crystal molecule 131 in the display medium layer 112 is driven by the electric field between the pixel electrode 122 and the shared electrode 123. When the electric field imposed on the crystal molecules 131 is removed fastly, the liquid crystal molecules 131 is in a twisted planar state, as shown in FIG. 6, the light, of which a wave length is in a visible light region, from a light source in outside environment is reflected by the crystal liquid molecules 131, to form a bright state and display a pattern corresponding to the display pixel electrode 122. When the electric field imposed on the crystal molecules 131 are removed slowly, the crystal molecules 131 are in a conic state, as shown in FIG. 7, the light from a light source in outside environment is absorbed after penetrating the crystal liquid molecules 131, to form a dark state, and the pattern corresponding to the pixel electrode 122 can not be displayed.

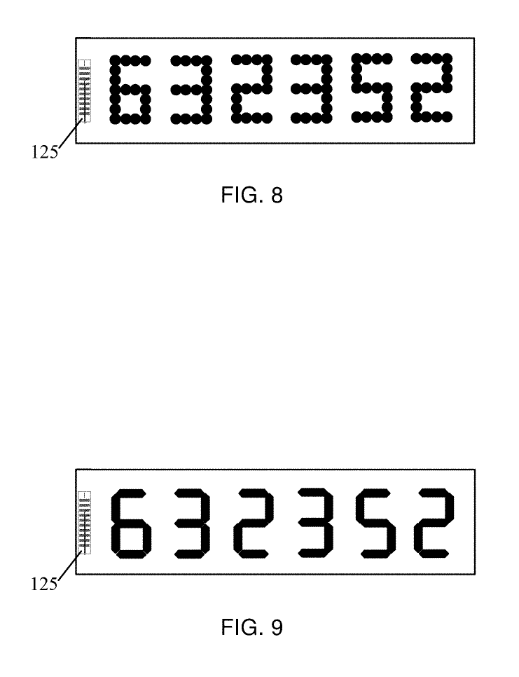

It should be noted that, the pixel electrode in the present embodiment may be segment electrode or dot-matrix electrode. When the pixel electrode is dot-matrix electrode, the battery is displayed in form of dot-matrix in display area corresponding to the pixel electrode and the shared electrode in the present embodiment of the present invention, as shown in FIG. 8. When the pixel electrode is segment electrode, the battery in the present embodiment of the present invention displays in form of segment matrix in display area corresponding to the pixel electrode and the shared electrode, as shown in FIG. 9.

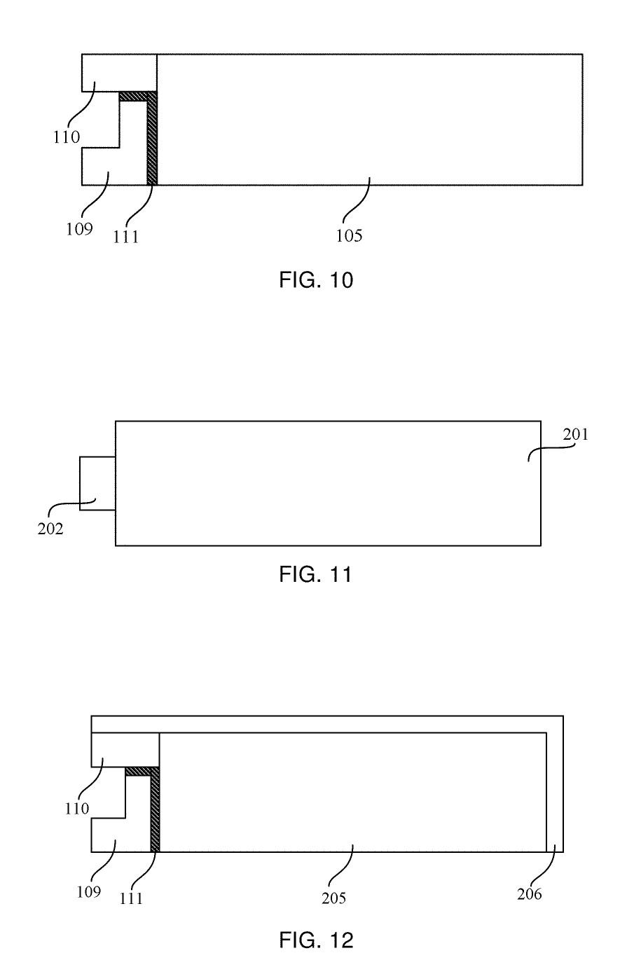

Further, as shown in FIG. 10, the battery in the present embodiment of the invention further includes a first electrode wiring 109 and a second electrode wiring 110; the second electrode current collector 105 and the first electrode wiring 109 and the second electrode wiring 110 are located on a same plane; the second electrode wiring 110 and the second electrode current collector 105 are conductive; the first electrode wiring 109 is conducted to the first electrode current collector 101 are conductive, and is insulated to the second electrode current collector 105 and the second electrode wiring 110.

Specifically, the battery in the embodiment of the present invention is further includes an insulation tape 111, where the insulation tape 111 is located on a same plane with the second electrode current collector 105, the first electrode wiring 109 and the second electrode wiring 110, and isolates the first electrode wiring 109 from the second electrode current collect 105 and the second electrode wiring 110.

Correspondingly, as shown in FIG. 11, the first electrode current collector 101 includes an attaching part 201 and a protruding part 202, where the attaching part 201 is attached to the first electrode material 102, and the protruding part 202 is attached to the first electrode wiring 109.

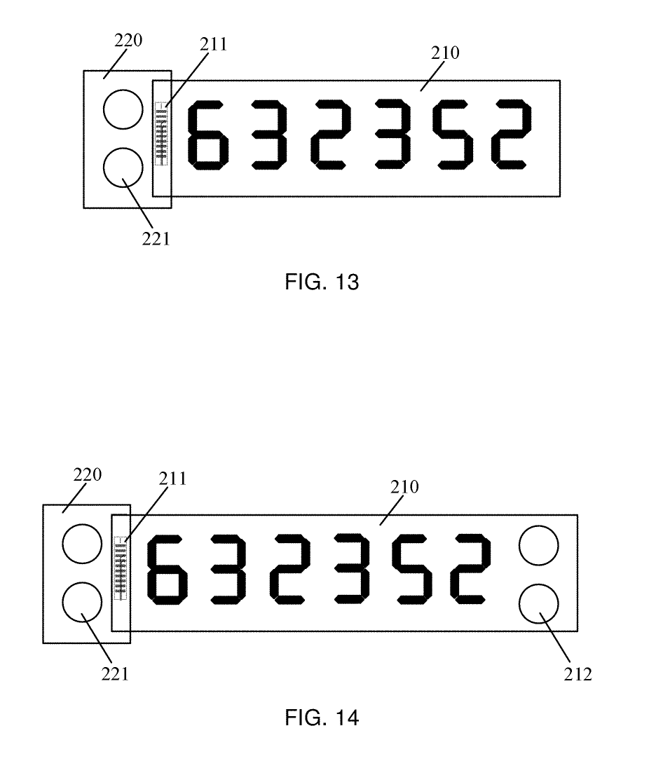

Further, as shown in FIG. 12, the second electrode current collector 105 includes a center part 205 and an edge part 206, wherein the center part 205 is attached to the second electrode material 104.

Where, the first connection part 125 located at the edge of the battery is connected to the first electrode wiring 109, and is connected to the second electrode wiring 110 or an edge part 206 in the second electrode current collector 105. Specifically, a first via hole exists between a layer on which the first connection part 125 is located, and the first electrode wiring 109, and a second via hole exists between the layer on which the first connection part 125 is located, and the second electrode wiring 110 or the edge part 206 in the second electrode current collector 105. Correspondingly, the first connection part 125 is connected to the first electrode wiring 109 through the first via hole, and is connected to the second electrode wiring 110 or the edge part 206 in the second electrode current collector 105 through the second via hole.

According to embodiments of the present invention, one of the electrode current collectors in the battery is multiplexed as one surface layer of a printed circuit board and implements display function on another surface layer of the printed circuit board, so as to implement integration of a displayer and a battery. In this way, an electronic device on which the battery is located requires no extra displayer, which reduces limitation of volume of the battery and the displayer in the electronic device without enlarging volume of the electronic device, and promoting the battery capacity of the electronic device and the using experience of the user as well.

Based on the battery with display function described above, embodiments of the present invention further provide an electronic device containing the above battery. As shown in FIG. 13, the electronic device includes the battery 210 and a main circuit board 220, which is arranged with one or more electronic elements 221; and the electronic element 221 may be one or more of the following items: a touch button, a resistance, a capacity, a metallic elastic piece and a micro processor. The battery 210 is connected to the main circuit board 220 via a first junction 211 located at the edge of the battery, and exchanges information with at least one of the electronic elements 221 on the main circuit board 220. For example, the battery 210 exchanges information with the micro processor on the main circuit board 220 via the first connection part 211.

Further, the electric elements 212 are welded on the battery 210 via a pad. As shown in FIG. 14, the electronic elements 212 are connected to the first junction 211, and may be one or more of the following items: a touch button, a resistance, a capacity, a metallic elastic piece and a micro processor.

Specifically, when the electronic elements 212 and the first junction 211 are located on a same layer, the first junction 211 is connected to the electronic elements 212 via printed conductor; when the electronic element 212 and the first junction 211 are located at different layers, the first junction 211 is connected to the electronic element 212 through a printed conductor and the via hole.

Further, the battery 210 may also be connected to the main circuit board 220 via a second junction located at the edge of the battery, and supplies power to at least one electronic element 221 on the main circuit board 220.

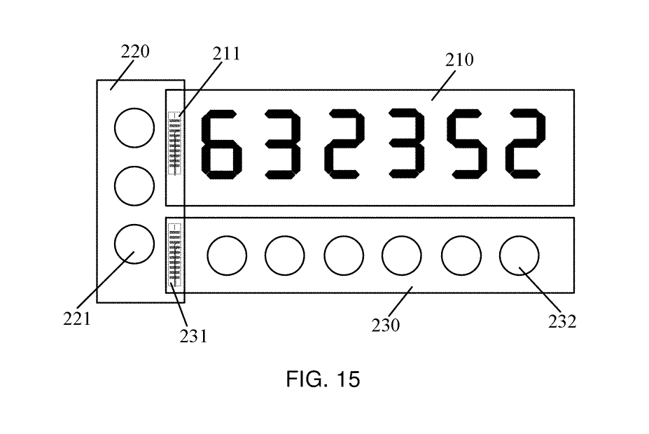

Further, the electronic device in embodiments of the present invention further includes an auxiliary circuit board 230, and the auxiliary circuit board 230 is connected to the mail circuit board 220 via a third junction 231 on the edge of the auxiliary circuit board 230 itself. The auxiliary circuit board 230 is arranged with one or more electronic elements 232. As shown in FIG. 15, the electronic elements 232 are connected to the third junction 231, and may be one or more of the following items: a touch button, a resistance, a capacity, and a metallic elastic piece.

According to embodiments of the present invention, one of the electrode current collectors in the battery is multiplexed as one surface layer of a printed circuit board and implements display function on another surface layer of the printed circuit board, so as to implement integration of a displayer and a battery. In this way, an electronic device on which the battery is located requires no extra displayer, which reduces limitation of volume of the battery and the displayer in the electronic device without enlarging volume of the electronic device, and promoting the battery capacity of the electronic device and the using experience of the user as well.

What is described above is merely specific implementation manners of the present invention, but does not limit the protection scope of the present invention. Variations and modifications that can be easily figured out by persons skilled in the art within the technical scope disclosed in the present invention shall all fall within the protection scope of the present invention. Therefore, the protection scope of the present disclosure is subject to the appended claims.

What is claimed is:

1. A battery with display function, comprising:
a non-volatile display layer, a substrate layer and a power layer, wherein the substrate layer is located between the non-volatile display layer and the power layer;
the non-volatile display layer comprises a first electrode layer, a display medium layer, a second electrode layer and a transparent medium layer, the first electrode layer is located between the display medium layer and the substrate layer, the display medium layer is located between the first electrode layer and the second electrode layer, the second electrode layer is located between the transparent medium layer and the display medium layer, the second electrode layer is placed on a surface of the transparent media layer, the transparent medium layer contacts the display medium layer via the surface, the display medium layer is filled with display cells, and the transparent medium layer and the second electrode layer are made of transparent material;
the power layer comprises a first electrode current collector, a first electrode material, electrolyte, a second electrode material and a second electrode current collector, the electrolyte is located between the first electrode material and the second electrode material, the first electrode material is located between the first electrode current collector and the electrolyte, and the second electrode material is located between the second electrode current collector and the electrolyte; and
the substrate layer is a PCB substrate, both the second electrode current collector and the first electrode layer are placed on the PCB substrate; and the second electrode current collector, the PCB substrate and the first electrode layer constitute a PCB structure.

2. The battery according to claim 1, wherein the transparent medium layer and the PCB substrate forms a sealed space with the display medium layer sealed in the sealed space.

3. The battery according to claim 1, wherein the display cells are microcapsules or liquid crystal molecules.

4. The method according to claim 3, wherein the microcapsule contains transparent liquid, and a plurality of white particles with charges of a first polarity and a plurality of black particles with charges of a second polarity in the transparent liquid.

5. The battery according to claim 3, wherein when the display cells are liquid crystal molecules, the battery further comprises a first alignment film and a second alignment film, the first alignment film is located between the first electrode layer and the display medium layer; the second alignment film is located between the display medium layer and the second electrode layer.

6. The battery according to claim 3, wherein the liquid crystal molecules are bistable liquid crystal molecules.

7. The battery according to claim 1, wherein the first electrode layer comprises a first electrode and a first electrode lead connected to the first electrode, the second electrode layer comprises a second electrode and a second electrode lead connected to the second electrode, and the first electrode and the second electrode are located above the display medium layer and under the display medium layer, respectively.

8. The battery according to claim 7, wherein the battery further comprises a first connection part;
the first electrode is connected to the first connection part via the first electrode lead and obtains external power supply via the first connection part; and the second electrode is connected to the first connection part via the second electrode lead and obtains external power supply via the first connection part.

9. The battery according to claim 7, wherein the first electrode is a pixel electrode, and the second electrode is a shared electrode;
the first electrode layer comprises a plurality of scan lines, a plurality of data lines and a plurality of pixel cells; each pixel cell is located in a matrix formed by the scan lines and the data lines in the first electrode layer and is surrounded by a corresponding scan line and a corresponding data line.

10. The battery according to claim 9, wherein the first electrode layer further comprises a display driver, the display driver is connected to the pixel cells in the first electrode layer via the scan lines and the data lines and is configured to drive the pixel cells in the first electrode layer.

11. The battery according to claim 7, wherein when the first electrode is a shared electrode, the second electrode is a pixel electrode;
the second electrode layer comprises a plurality of scan lines, a plurality of data lines and a plurality of pixel cells; each pixel cell is located in a matrix formed by the scan lines and the data lines in the second electrode layer, and is surrounded by a corresponding scan line and a corresponding data line.

12. The battery according to claim 11, wherein the second electrode layer further comprises a display driver, the display driver is connected to the pixel cells in the second electrode layer via the scan lines and the data lines and is configured to drive the pixel cells in the second electrode layer.

13. The battery according to claim 9, wherein the pixel cell comprises a thin-film transistor and a pixel electrode connected to the thin-film transistor.

14. The battery according to claim 1, wherein the battery further comprises a first electrode wiring and a second electrode wiring; the second electrode current collector and the first electrode wiring and the second electrode wiring are located on a same plane; the second electrode wiring and the second electrode current collector are conductive; the first electrode wiring and the first electrode current collector are conductive, and the first electrode wiring is insulated to the second electrode current collector and the second electrode wiring.

15. An electronic device containing the battery according to claim 1, wherein the electronic device further comprises a main circuit board, the main circuit board is arranged with one or more electronic elements, the battery is connected to the main circuit board via a first junction part at an edge of the battery.

16. The electronic device according to claim 15, wherein the battery is connected to the main circuit board via a second junction located at the edge of the battery itself.

17. The electronic device according to claim 15, wherein the electronic device further comprises an auxiliary circuit board; the auxiliary circuit board is connected to the mail circuit board via a third junction located at an edge of the auxiliary circuit board itself, and the auxiliary circuit board is arranged with one or more electronic elements.
